(19) United States
(12) Patent Application Publication
(10) Pub. No.: US 2012/0231394 A1
(43) Pub. Date: Sep. 13, 2012

(54) IMAGEABLE ELEMENTS WITH COLORANTS

(76) Inventors: Christopher D. Simpson, Osterode (DE); Harald Baumann, Osterode/Harz (DE); Joachim Pengler, Munich (DE); Michael Flugel, Osterode/Harz (DE)

(21) Appl. No.: 13/480,634

(22) Filed: May 25, 2012

Related U.S. Application Data
(62) Division of application No. 12/397,429, filed on Mar. 4, 2009.

(51) Int. Cl. G03F 7/20

(52) U.S. Cl. 430/302

(57) ABSTRACT

Both positive-working and negative-working imageable element can have a radiation-sensitive imageable layer that has at least one pigment colorant that does not change color when heated, and at least one dye that can change color when heated. The dye is soluble in the solvent or mixture of solvents used to coat the radiation-sensitive imageable layer on a substrate and the pigment colorant is not. This combination of pigment colorant and dye provide excellent image contrast after imaging, development, and postbaking. The pigment colorant and the dye independently have a maximum absorption of from about 480 to about 700 nm.

### RELATED APPLICATION

This is a divisional application of recently allowed, copending, and commonly assigned U.S. Ser. No. 12/397,429, which was filed Mar. 4, 2009.

### FIELD OF THE INVENTION

This invention relates to imageable elements that contain certain colorants that allow a visible and measurable optical density difference between elements that are baked after imaging and processing, and those that are not baked. This invention also relates to a method of providing imaged and processed elements such as lithographic printing plates.

### BACKGROUND OF THE INVENTION

Radiation-sensitive compositions are routinely used in the preparation of imageable materials including lithographic printing plate precursors. Such compositions generally include a radiation absorbing compound or sensitizer, a binder, and in some instances initiator compositions and polymerizable components, each of which has been the focus of research to provide various improvements in physical properties, imaging performance, and image characteristics.

Recent developments in the field of printing plate precursors concern the use of radiation-sensitive compositions that can be imaged by means of lasers or laser diodes. Laser exposure does not require conventional silver halide graphic arts films as intermediate information carriers (or “masks”) since the lasers can be controlled directly by computers. High-performance lasers or laser-diodes that are used in commercially-available image-setters generally emit radiation in a specific region of the electromagnetic spectrum, and thus the radiation-sensitive compositions are required to be sensitive in the regions appropriate for a specific imaging laser.

Radiation-sensitive compositions and the imageable elements in which they incorporated are generally either negative-working or positive-working. For negative-working imageable elements, exposed regions in the radiation-sensitive compositions are hardened and non-exposed regions are usually washed off during development. For positive-working imageable elements, the exposed regions are dissolved in a developer and the non-exposed regions become an image.

The literature that describes various components of such imageable elements includes hundreds of publications, and thus they are too numerous to mention here. The patent literature is full of teaching relating to various problems that the industry has been addressing for the last several decades, especially as the “computer-to-plate” (CTP) imageable elements and equipment became prominent in the 1990's. Thus, there has been considerable efforts to develop both positive- and negative-working elements with high imaging sensitivity (high photospeed), fast developability in various developing solutions (generally pH 3 to 14), high resistance to degradation to pressroom chemicals (“chemical resistance”), plate durability, storage stability, high image stability, low environmental impact, and high run length.

Some of these problems have been solved by designing unique polymeric binders that are used in imageable layers to provide a matrix for the various imaging components. For example, U.S. Pat. No. 4,511,645 (Kioke et al.) describes the use of polymeric binders having unsaturated side chains in negative-working imageable elements to stabilize image formation. In addition, EP 0 924 570A1 (Fujimaki et al.) describes UV/visible-sensitive compositions and imageable elements containing polymeric binders having amido groups in side chains to increase alkaline solution solubility.

After imaging, printing plates are usually inspected to make sure that the desired image has been obtained. For printing plate processed off-press, this inspection can occur easily before mounting on the printing press. The plate manufacturer often adds a colorant to the radiation-sensitive imaging composition to facilitate this inspection.

### SUMMARY OF THE INVENTION

This invention provides an imageable element comprising a substrate and having thereon a radiation-sensitive imageable layer that comprises at least one pigment colorant that does not change color when heated and at least one dye that can change color when heated, wherein the dye is soluble in the solvent or mixture of solvents used to coat the radiation-sensitive imageable layer onto the substrate, and the pigment colorant is not, and

wherein the pigment colorant and the dye independently have a maximum absorption of from about 480 to about 700 nm.

The invention also provides a method of providing a lithographic printing plate comprising:

A) imagewise exposing the imageable element of this invention to provide exposed and non-exposed regions,

B) processing the imagewise exposed imageable element to provide a lithographic printing plate, and

C) baking the lithographic printing plate at a temperature of from about 150 to about 300° C.,

wherein the optical density of said lithographic printing plate, as measured using a cyan filter:

i) after steps A and B and before step C is at least 0.7,

ii) after steps A, B, and C is at least 0.5,

the difference between the optical density of the exposed regions before step A and the optical density of the exposed regions after step B but before step C, is less than 0.05, and the difference between the optical density of the exposed regions between steps B and C, and the optical density of the exposed regions after step C, is at least 0.2.

We have discovered that the present invention solves the problem of the need for image contrast in printing plates after imaging, development, and post baking. In addition, the invention provides imageable elements that have high photospeed, good shelf life, and high stability in safe light conditions.

The imaged, developed, and postbaked printing plates provided by this invention have a visually observable and measureable optical density change in the imaged regions before and after postbaking of at least 0.2.

The advantages of this invention are provided by using a combination of a pigment colorant that is insoluble in the solvents used for coating the radiation-sensitive imageable layer and a dye that is soluble in those coating solvents. In addition, the pigment colorant does not change color when heated at a temperature of up to 170° C., but the dye can change color when so heated.

If the dye or pigment colorant is used alone, problems are evident. For example, if only the dye is used, the printing plate is bleached too strongly during the postbaking step that printing plate inspection and automated contrast reading are difficult. If the pigment colorant is used alone, the printing plate is hardly bleached during postbaking, making it difficult to determine if the printing plate has been baked at all. Thus, we found that the combination of pigment colorant and dye solves these problems.

### DETAILED DESCRIPTION OF THE INVENTION

Unless the context indicates otherwise, when used herein, the terms “imageable element”, “lithographic printing plate precursor”, and “printing plate precursor” are meant to be references to embodiments of the present invention.

In addition, unless the context indicates otherwise, the various components described herein such as “pigment colorant”, “dye”, “initiator”, “free radically polymerizable component”, “radiation absorbing compound”, “polymeric binder”, and similar terms also refer to mixtures of such components. Thus, the use of the articles “a”, “an”, and “the” is not necessarily meant to refer to only a single component.

Moreover, unless otherwise indicated, percentages refer to percents by total dry weight, for example, weight % based on total solids of either an imageable layer or radiation-sensitive composition. Unless otherwise indicated, the percentages can be the same for either the dry imageable layer or the total solids of radiation-sensitive composition.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers, homopolymers, and copolymers, which are defined for this invention to have a molecular weight of at least 500.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Pigments Colorants and Dyes

The pigment colorants useful in the practice of this invention can be an organic colorant that is generally insoluble at less than 0.1 g/liter in coating solvents generally used to apply the radiation-sensitive imageable layer to a substrate (defined below). For example, the pigment colorants are generally insoluble at less than 0.1 g/liter in organic solvents having hydroxyl, ester, ether, carbonyl, carboxy, amide, or nitrile groups and have a boiling point of from about 30 to about 250° C. Such solvents include but are not limited to, methanol, ethanol, iso-propanol, butanol, octanol, ethyl acetate, propylacetate, iso-butyl acetate, methyl lactate, ethyl lactate, methyl ethyl ketone, diethyl ketone, methyl iso-butyl ketone, formic acid, acetic acid, propionic acid, N-methylpyrrolidone, dimethylformamide, dimethylacetamide, dimethylsulfoxide, tetrahydrofurane, dioxane, dioxolane, acetonitril, propoinitril, ethylene glycol monomethylther, ethylene glycol monoethylether, propylene glycol monomethylether, propylene glycol monomethylether, propylene glycol methylether acetate, propylene glycol, γ-butyrolactone and ethylether acetate. Mixtures of two or more of these solvents can be used also. Some solvent systems include water as a co-solvent.

Classes of useful pigments colorants include but are not limited to, phthalocyanines, perylenes, and azo pigments.

One or more pigment colorants are present in an total amount of at least 0.2 weight %, and typically from about 0.2 to about 20 weight %, or from about 1 to about 10 weight %. The optimal amount of pigment colorant can be adjusted with that of the dye (described below) with routine experimentation to provide the desired optical density characteristics described below.

The dyes useful in this invention are generally soluble (equal to or more than 5 g/liter) in the coating solvents described above. Useful classes of dyes include but are not limited to, cyanine, triarylmethane, azo, and merocyanine dyes.

One or more dyes of this type can be present in a total amount of at least 0.2 weight %, typically from about 0.2 to about 20 weight %, or from about 1 to about 10 weight %.

The pigment colorants and the dyes described above independently have a maximum absorption (λₘₐₓ) of from about 480 to about 700 nm or typically from about 600 to about 700 mu, as determined using a conventional spectrophotometer. This differentiates these compounds from sensitizers (described below) that are used to provide sensitivity for imaging at various wavelengths.

The dyes and pigment colorants can be present at the same or different amounts. The compounds can be obtained from various commercial sources.

After steps A and B and before step C of the method of this invention, the optical density of the imaged and developed element (such as lithographic printing plate), as measured using a cyan filter, is at least 0.7 or from about 0.9 to about 1.2.

In addition, after steps A, B, and C of the method, the optical density of the imaged, developed, and postbaked element (such as a lithographic printing plates), as measured using a cyan filter, is at least 0.5.

The difference between the optical density of the exposed regions before step A and the optical density of the exposed regions after step B but before step C, is less than 0.05, and

the difference between the optical density of the exposed regions between steps B and C, and the optical density of the exposed regions after step C, is at least 0.2. In some embodiments, the difference between the optical density of the exposed regions between steps B and C, and the optical density of the exposed regions after step C, is from about 0.2 to about 0.4.

### Imageable Elements

The imageable elements of this invention can be used for the production of printing plates suitable or intended primarily for lithographic printing, letterpress printing, gravure printing, and screen printing. For example, the imageable elements can be lithographic printing plate precursors of various types, particularly thermally imageable (such as computer-to-plate) negative-working and positive-working lithographic printing plate precursors.

Some embodiments of such positive-working imageable elements comprise a processing solution removable inner layer and an ink-receptive outer layer. In other embodiments, the imageable elements include only a single imageable layer that is removable in the processing solution. The imageable layer(s), which are composed of water- or alkali-soluble polymeric compositions, are generally disposed on an aluminum-containing substrate. More details of such elements are provided as follows.

The substrates are generally provided initially as an electrochemically grained support having aluminum as the predominant component, and including supports of pure aluminum and aluminum alloys. Thus, the electrochemically grained metal support can be composed of pure aluminum, aluminum alloys having small amounts (up to 10% by weight) of other elements such as manganese, silicon, iron, titanium, copper, magnesium, chromium, zinc, bismuth, nickel, or zirconium, or be polymeric films or papers on which a pure aluminum or aluminum alloy sheet is laminated or deposited (for example, a laminate of an aluminum sheet and a polyester film).

The thickness of the resulting aluminum-containing substrate can be varied but should be sufficient to sustain the wear from printing and thin enough to wrap around a printing form. Generally, support sheets have a thickness of from about 100 to about 700 μm.

The substrates can be prepared as continuous webs or coiled strips to provide substrates as continuous webs that can be cut into desired sheets at a later time.

The aluminum surface of the support is generally cleaned, roughened, and anodized using suitable known procedures. For example, the surface may be roughened (or grained) by known techniques, such as mechanical roughening, electrochemical roughening, or a combination thereof (multi-graining). Electrochemically graining can be carried out in a suitable manner as described for example in U.S. Pat. No. 7,049,048 (Hunter et al.). In some embodiments, the surface of the aluminum-containing support can be electrochemically grained using the procedure and chemistry described in U.S. Patent Application Publication 2008/0003411 (Hunter et al.).

While this electrochemically grained metal sheet can now be used as a substrate, it is usually subjected to additional treatments before such use. Generally, the electrochemically grained metal surface is etched with an alkaline solution to remove at least 100 mg/m², and typically to remove from about 100 to about 1000 mg/m². The electrochemically grained aluminum support can then be anodized in an alternating current passing through a sulfuric acid solution (5-30%) to form an oxide layer on the metal surface. When phosphoric acid is used for anodization, the conditions may be varied, as one skilled in the art would readily know.

The aluminum-containing support is then usually treated to provide a hydrophilic interlayer to render its surface more hydrophilic with, for example, a post-treatment solution containing a homopolymer of vinyl phosphonic acid (PVPA) or a vinyl phosphonic acid copolymer such as a copolymer derived from vinyl phosphonic acid and (meth)acrylic acid (that is either methacrylic acid, acrylic acid, or both). Other treatments are described in U.S. Pat. No. 7,416,831 (Hayashi et al.). Typically, the electrochemically grained, etched, and anodized aluminum support is treated with poly(vinyl phosphonic acid).

The backside (non-imaging side) of an aluminum substrate may be coated with antistatic agents and/or slipping layers or a matte layer to improve handling and “feel” of the imageable element.

The substrate can also be a cylindrical surface having the imageable layer thereon, and thus be an integral part of the printing press. The use of such imaging cylinders is described for example in U.S. Pat. No. 5,713,287 (Gelbart).

The substrates can be used to prepare a wide variety of negative- and positive-working imageable elements that are generally lithographic printing plate precursors and include one or more ink-receptive layers disposed on the substrate. That is, they include one or more imageable layers besides any layers generally used as subbing layers, adhesion layers, protective cover layers, or for other non-imaging purposes.

The imageable layers (hence elements) can be made sensitive to any suitable thermal imaging radiation including UV, visible, and infrared radiation having a maximum exposure wavelength of from about 150 to about 1500 nm. In some embodiments, the imageable elements are “violet” sensitive at from about 300 to about 450 nm, and in other embodiments, they are thermally sensitive at from about 700 to about 1400 nm. The imageable elements can be designed for imaging on a variety of processing apparatus and for development off-press using the present invention in conventional developing apparatus.

Negative-Working Imageable Elements

There are numerous publications in the art relating to negative-working imageable compositions and elements that can be prepared and used in the present invention. Useful negative-working compositions generally include a polymerizable component (such as a free-radically polymerizable monomer, oligomer, or polymer, or acid-crosslinked compound), an initiator composition (such as compounds that generate free radicals or acids, or promote cationically or acid-catalyzed polymerization or crosslinking) such as onium salts, triazines, metallocenes, polycarboxylic acids, hexaaryl bisimidazoles, and borate salts, appropriate sensitizers or radiation absorbing compounds for a specific radiation sensitivity (including photothermal conversion materials) such as carbon blacks, IR dyes, coumarins, oxazoles, triarylmethanes, and styryl-substituted aromatic compounds.

Some useful negative-working imageable compositions and elements include but are not limited to, those described in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. Nos. 4,511,645 (Koike et al.), 6,027,857 (Teng), 6,309,792 (Hauck et al.), 6,569,603 (Furukawa et al.), 7,045,271 (Tao et al.), 7,049,046 (Tao et al.), 7,169,334 (Baumann et al.), 7,175,969 (Ray et al.), 7,183,039 (Timpe et al.), 7,279,255 (Tao et al.), 7,285,372 (Baumann et al.), 7,291,438 (Sakurai et al.), 7,326,521 (Tao et al.), 7,332,253 (Tao et al.), 7,442,486 (Baumann et al.), and 7,452,638 (Yu et al.), and U.S. Patent Application Publications 2003/0064318 (Huang et al.), 2004/0265736 (Aoshima et al.), 2005/0266349 (Van Damme et al.), and 2006/0019200 (Vermeersch et al.). Other negative-working compositions and elements are described for example in Japanese Kokai 2000-187322 (Takasaki), 2001-330946 (Saito et al.), 2002-040631 (Sakurai et al.), 2002-341536 (Miyamoto et al.), and 2006-317716 (Hayashi). Other negative-working imageable elements are described in copending and commonly assigned U.S. Ser. No. 11/949,810 (filed Dec. 4, 2007 by Baumann, Dwars, Strehmel, Simpson, Savariar-Hauck, and Hauck).

In generally, such compositions and imageable layers include one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated components that can be polymerized or crosslinked include ethylenically unsaturated polymerizable monomers that have one or more of the polymerizable groups, including unsaturated esters of alcohols, such as acrylate and methacrylate esters of polyols. Oligomers and/or prepolymers, such as urethane acrylates and methacrylates, epoxide acrylates and methacrylates, polyester acrylates and methacrylates, polyether acrylates and methacrylates, and unsaturated polyester resins can also be used. In some embodiments, the free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

The free radically polymerizable component can also be one or more of the non-polymeric components described above that have 1H-tetrazole groups and are also polymerizable in the presence of free radicals. Such components generally are mono-, di-, or triacrylates, or they are styryl compounds to which the 1H-tetrazole groups are attached. As noted above, there can be multiple free radically polymerizable components present in the radiation-sensitive composition.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (Fujimaki et al.), beginning with paragraph [0170], and in U.S. Pat. Nos. 6,309,792 (Hauck et al.), 6,569,603 (Furukawa), and 6,893,797 (Munnelly et al.). The free radically polymerizable component can also include carboxy groups as described for example in U.S. Pat. No. 7,153,632 (Saraiya et al.).

The one or more free radically polymerizable components (monomeric, oligomeric, or polymeric) can be present in the radiation-sensitive composition or imageable layer in an amount of at least 10 weight % and up to 70 weight %, and typically from about 20 to about 50 weight %, based on the total dry weight. The weight ratio of the free radically polymerizable component to the total polymeric binders (described below) is generally from about 5:95 to about 95:5, and typically from about 10:90 to about 90:10, or even from about 30:70 to about 70:30.

The radiation-sensitive composition (and imageable layer) also includes an initiator composition that is capable of generating free radicals sufficient to initiate polymerization of all the various free radically polymerizable components upon exposure of the composition to imaging radiation. Initiator compositions are used that are appropriate for the desired imaging wavelength(s). More typically, they are responsive to either UV (or “violet”) radiation at a wavelength of from about 150 to about 475 nm (or from about 300 to about 450 nm) or to infrared radiation of at least 700 nm and up to and including 1400 nm.

In general, suitable initiator compositions comprise initiators that include but are not limited to, amines (such as alkanol amines), thiol compounds, N,N-dialkylaminobenzoic acid esters, N-arylglycines and derivatives thereof (such as N-phenylglycine), aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). For “violet”-sensitive compositions, the initiators are hexaarylbiimidazoles, oxime esters, or trihalomethyl substituted triazines.

Useful IR-sensitive radiation-sensitive compositions include an onium salt including but not limited to, a sulfonium, oxysulfoxonium, oxysulfonium, sulfoxonium, ammonium, selenonium, arsonium, phosphonium, diazonium, or halonium salt. Further details of useful onium salts, including representative examples, are provided in U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), and 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art.

The halonium salts are useful such as the iodonium salts. In one embodiment, the onium salt has a positively-charged iodonium, (4-methylphenyl)[4-(2-methylpropyl)phenyl]-moiety and a suitable negatively charged counterion. Typically anions for the iodonium initiators are chloride, bromide, nitrated, perchlorate, hexafluorephosphate, tetrafluoroboate, tetraphenylborate, and triphenylbutylborate anions. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

Useful boron-containing compounds include organic boron salts that include an organic boron anion such as those described in U.S. Pat. No. 6,569,603 (Furukawa) that is paired with a suitable cation such as an alkali metal ion, an onium, or a cationic sensitizing dye. Useful onium cations for this purpose include but are not limited to, ammonium, sulfonium, phosphonium, iodonium, and diazonium cations. They may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole.

Other useful initiator compositions include one or more azine compounds as described for example in U.S. Pat. No. 6,936,384 (Munnelly et al.). These compounds are organic heterocyclic compounds containing a 6-membered ring formed from carbon and nitrogen atoms. Azine compounds include heterocyclic groups such as pyridine, diazine, and triazine groups, as well as polycyclic compounds having a pyridine, diazine, or triazine substituent fused to one or more aromatic rings such as carbocyclic aromatic rings. Thus, the azine compounds include, for example, compounds having a quinoline, isoquinoline, benzodiazine, or naphthodiazine substituent. Both monocyclic and polycyclic azine compounds are useful.

Useful azine compounds are triazine compounds that include a 6-membered ring containing 3 carbon atoms and 3 nitrogen atoms such as those described in U.S. Pat. Nos. 6,309,792 (Hauck et al.), 6,010,824 (Komano et al.), 5,885,746 (Iwai et al), 5,496,903 (Watanabe et al.), and 5,219,709 (Nagasaka et al.).

The azinium form of azine compounds can also be used if desired. In azinium compounds, a quaternizing substituent of a nitrogen atom in the azine ring is capable of being released as a free radical. The alkoxy substituent that quaternizes a ring nitrogen atom of the azinium nucleus can be selected from among a variety of alkoxy substituents.

Halomethyl-substituted triazines, such as trihalomethyl triazines, are useful in the initiator composition. Representative compounds of this type include but are not limited to, 1,3,5-triazine derivatives such as those having 1 to 3-CX₃ groups wherein X independently represent chlorine or bromine atoms, including polyhalomethyl-substituted triazines and other triazines, such as 2,4-trichloromethyl-6-methoxyphenyl triazine, 2-phenyl-4,6-bis(trichloromethyl)-s-triazine, 2,4,6-tris(trichloromethyl)-s-triazine, 2-methyl-4,6-bis(trichloromethyl)-s-triazine, 2-(styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bis(trichloromethyl)-s-triazine, 2-(4-ethoxynaphtho-1yl)-4,6-bis(trichloromethyl)-s-triazine, and 2-(4-(2-ethoxyethyl)-naphtho-1-yl)-4,6-bis(trichloromethyl)-s-triazine], 2-(4-methylthiophenyl)-4,6-bis(trichloromethyl)-2-triazine, 2-(4-chlorophenyl-4,6-bis(trichloromethyl)-2-triazine, 2,4,6-tri(trichloromethyl)-2-triazine, and 2,4,6-tri(tribromomethyl)-2-triazine.

The azine compounds may be used alone or in combination with one or more co-initiators such as titanocenes, mono- and polycarboxylic acids, hexaarylbisimidazoles, as described for example in U.S. Pat. No. 4,997,745 (Kawamura et al.).

Particularly useful initiators for use with IR-sensitive radiation-sensitive compositions are diaryliodonium borates in which the aryl groups of the cation can be substituted or unsubstituted. Possible substituents are described below in relation to Structure (IB). The borate anion has four valences filled with the same or different organic groups, for example, as described below for Structure (IBz).

Useful iodonium cations are well known in the art including but not limited to, U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), and 6,051,366 (Baumann et al.). For example, a useful iodonium cation includes a positively charged iodonium, (4-methylphenyl)[4-(2-methylpropyl)phenyl]-moiety and a suitable negatively charged borate counterion.

Useful diaryliodonium borates include, but are not limited to, those represented by the following Structure (IB):

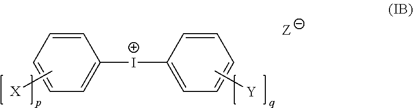

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono- and poly-, branched and linear haloalkyls), substituted or unsubstituted alkyloxy having 1 to 20 carbon atoms (for example, substituted or unsubstituted methoxy, ethoxy, iso-propoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds (that is, they have the same groups on both phenyl rings) are useful.

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5, provided that either p or q is at least 1. Typically, both p and q are at least 1, or each of p and q is 1. Thus, it is understood that the carbon atoms in the phenyl rings that are not substituted by X or Y groups have a hydrogen atom at those ring positions.

Z^{⊖} is an organic anion represented by the following Structure

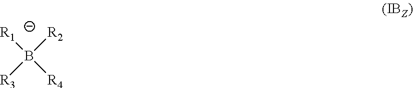

wherein R₁, R₂, R₃, and R₄ are independently substituted or unsubstituted alkyl groups having 1 to 12 carbon atoms (such as methyl, ethyl, n-propyl, iso-propyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. Z^{⊖} can be a tetraphenyl borate wherein the phenyl groups are substituted or unsubstituted (for example, all are unsubstituted). Representative iodonium borate compounds include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]-borate, 4-methoxyphenyl-4′-cyclohexylphenyliodonium tetrakis(penta-fluorophenyl)borate, 4-methylphenyl-4′-dodecylphenyliodonium tetrakis(4-fluorophenyl)borate, bis(dodecylphenyl)iodonium tetrakis(pentafluorophenyl)-borate, and bis(4-t-butylphenyl)iodonium tetrakis(1-imidazolyl)borate. Mixtures of two or more of these compounds can also be used in the iodonium borate initiator composition.

The various free radical generating compounds (initiators) may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole.

Co-initiators can also be used, such as metallocenes (including titanocenes and ferrocenes), polycarboxylic acids (for example as described in EP 1,079,972 by Hauck et al.), haloalkyl triazines, thiols, or mercaptans (such as mercaptotriazoles), borate salts, and photooxidants containing a heterocyclic nitrogen that is substituted by an alkoxy or acyloxy group, as described in U.S. Pat. No. 5,942,372 (West et al.).

Metallocenes are organometallic compounds that have one or more cyclopentadienyl ligands that are optionally substituted at one or all of the ring carbons. Each carbon in the five-member ligand ring is coordinated to the transition metal center. Metallocenes are known for having a wide variety of transition metals including iron, titanium, tungsten, molybdenum, nickel, cobalt, chromium, zirconium, and manganese.

For example, ferrocenes have an iron center coordinated by at least one cyclopentadienyl ligand, but ferrocenes also include bicyclopentadienyl “sandwich” compounds. Suitable ferrocene compounds include those that have a hexhapto benzene ligand coordinated to the iron center. Examples of such compounds are described in Col. 7 of U.S. Pat. No. 6,936,384 (Munnelly et al.). Other suitable ferrocenes include compounds having halogenated, aryl-substituted, or haloaryl-substituted cyclopentadienyl ligands.

Titanocenes are also useful in the practice of this invention. Such compounds have a titanium center coordinated by at least one pentahapto cyclopentadienyl ligand and generally include additional ligands that may be known for organometallic complexes. Some suitable titanocene compounds include in their structures aryl ligands, haloaryl ligands, or pyrrole-substituted aryl ligands. Examples of useful titanocenes include those described in Col. 8 of U.S. Pat. No. 6,936,384 (noted above). One commercially available titanocene is (bis)cyclopentadienyl-(bis)2,6-difluoro-3-(pyrr-1-yl)phen-1-yl titanium sold by Ciba Specialty Chemicals as Irgacure® 784, as noted below with the Examples. Other suitable titanocenes are described in U.S. Pat. Nos. 4,548,891 (Riediker et al.), 4,590,287 (Riediker et al.), 5,008,302 (Husler et al.), 5,106,722 (Husler et al.), 6,010,824 (Komano et al.), and 6,153,660 (Fujimaki et al.).

It would be recognized by one skilled in the art that not every initiator (or co-initiator) can be used to advantage with every radiation absorbing compound (or sensitizer) described below. For example, some combinations of initiators and sensitizers may be unsuitable for photospeed or other properties, but it would require only routine experimentation in view of the teaching provided herein for a skilled worker to find the optimal combinations of initiators, optional co-initiators, and radiation absorbing compounds for a given spectral sensitivity to provide desired imaging, developability, and storage properties.

The free radical generating initiators in the initiator composition are generally present in the radiation-sensitive composition (or imageable layer) in an amount of at least 0.5% and up to and including 30%, and typically at least 2 and up to and including about 20%, based on total dry weight of the composition (or imageable layer). The optimum amount of the various initiator components (including co-initiators) may differ for various compounds and a given sensitivity of the radiation-sensitive composition can be designed by a one skilled in the art.

The radiation-sensitive composition (and imageable layer) generally includes one or more radiation absorbing compounds (or sensitizers) that absorb imaging radiation (or sensitize the composition to imaging radiation) having a spectral sensitivity of from the UV to the IR region of the electromagnetic spectrum, that is, at least 150 nm and up to and including 1400 nm. Some sensitizers can be used at any wavelength, but most sensitizers are optimally useful within certain wavelength ranges. For example, some sensitizers are optimal for use at an exposing wavelength of at least 150 nm and up to and including 650 nm (UV and violet to visible). Other sensitizers are particularly optimal for use for exposure to UV (violet) radiation of at least 150 nm and up to and including 475 nm, while still others are optimal for use at an exposure wavelength of at least 650 nm and up to and including 1500 nm (near IR and IR).

In some embodiments, the radiation-sensitive composition contains a UV sensitizer where the free-radical generating compound is UV radiation sensitive (that is at least 150 nm and up to and including 475 nm), thereby facilitating photopolymerization. In some other embodiments, the radiation sensitive compositions are sensitized to “violet” radiation in the range of at least 300 nm and up to and including 450 nm. Useful sensitizers for such compositions include certain pyrilium and thiopyrilium dyes and 3-ketocoumarins Some other useful sensitizers for such spectral sensitivity are described for example, in 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated π-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Sensitizers that absorb in the visible region of the electromagnetic spectrum (that is at least 400 nm and up to and including 650 nm) can also be used. Examples of such sensitizers are well known in the art and include the compounds described in Cols. 17-22 of U.S. Pat. No. 6,569,603 (noted above). Other useful visible and UV-sensitive sensitizing compositions include a cyanine dye and a co-initiator (as described above) as described in U.S. Pat. No. 5,368,990 (Kawabata et al.).

Other useful sensitizers for the violet/visible region of sensitization are the 2,4,5-triaryloxazole derivatives as described in WO 2004/074930 (Baumann et al.). These compounds can be used alone or with a co-initiator as described above. Useful 2,4,5-triaryloxazole derivatives can be represented by the Structure G-(Ar₁)₃ wherein Ar₁ is the same or different, substituted or unsubstituted carbocyclic aryl group having 6 to 12 carbon atoms in the ring, and G is a furan or oxazole ring, or the Structure G-(Ar₁)₂ wherein G is an oxadiazole ring. The Ar₁ groups can be substituted with one or more halo, substituted or unsubstituted alkyl, substituted or unsubstituted cycloalkyl, substituted or unsubstituted aryl, amino (primary, secondary, or tertiary), or substituted or unsubstituted alkoxy or aryloxy groups. Thus, the aryl groups can be substituted with one or more R′₁, through R′₃ groups, respectively, that are independently hydrogen or a substituted or unsubstituted alkyl group having from 1 to 20 carbon atoms (such as methyl, ethyl, iso-propyl, n-hexyl, benzyl, and methoxymethyl groups) substituted or unsubstituted carbocyclic aryl group having 6 to 10 carbon atoms in the ring (such as phenyl, naphthyl, 4-methoxyphenyl, and 3-methylphenyl groups), substituted or unsubstituted cycloalkyl group having 5 to 10 carbon atoms in the ring, a —N(R′₄)(R′₅) group, or a —OR′₆ group wherein R′₄ through R′₆ independently represent substituted or unsubstituted alkyl or aryl groups as defined above. At least one of R′₁ through R′₃ is an —N(R′₄)(R′₅) group wherein R′₄ and R′₅ are the same or different alkyl groups. Useful substituents for each Ar₁ group include the same or different primary, secondary, and tertiary amines.

Still another class of useful violet/visible radiation sensitizers includes compounds represented by the Structure Ar₁-G-Ar₂ wherein Ar₁ and Ar₂ are the same or different substituted or unsubstituted aryl groups having 6 to 12 carbon atoms in the ring, or Ar₂ can be an arylene-G-Ar₁ or arylene-G-Ar₂ group, and G is a furan, oxazole, or oxadiazole ring. Ar₁ is the same as defined above, and Ar₂ can be the same or different aryl group as Ar₁. “Arylene” can be any of the aryl groups defined for Ar₁ but with a hydrogen atom removed to render them divalent in nature.

The imageable layer includes one or more primary polymeric binders that provide the desired solubility in alkaline developers before exposure to imaging radiation. In some embodiments, the polymeric binder is a polymer having pendant 1H-tetrazole groups as described above.

Other useful polymeric binders include but are not limited to those having one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups may be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.). Other useful polymeric binders have vinyl groups in pendant groups that are described, for example in EP 1,182,033A1 (Fujimaki et al.) and U.S. Pat. Nos. 4,874,686 (Urabe et al.) and 7,041,416 (Wakata et al.) that are incorporated by reference, especially with respect to the general formulae (1) through (3) noted in EP 1,182,033A1. Some useful pendant reactive vinyl groups are alkenyl groups including but not limited to allyl esters, styryl, and (meth)acryloyl groups. For example, such groups can be provided by allyl (meth) acrylates, or by reacting a polymer precursor with an allyl halide, 4-vinylbenzyl chloride, or (meth)acryloyl chloride using conditions that would be apparent to a skilled worker in the art.

Additional useful polymeric binders may be any of those known in the art for use in negative-working radiation-sensitive compositions other than those mentioned above. The polymeric binder(s) may be present in an amount of from about 1.5 to about 70 weight % and typically from about 1.5 to about 40%, based on the dry coated weight of the radiation-sensitive composition (or imageable layer), and it may comprise from about 30 to about 60 weight % of the dry weight of all polymeric binders.

The polymeric binders may be homogenous, that is, dissolved in the coating solvent, or may exist as discrete particles. Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (Fujimaki et al.) and U.S. Pat. Nos. 6,309,792 (Hauck et al.), 6,352,812 (Shimazu et al.), 6,569,603 (Furukawa et al.), and 6,893,797 (Munnelly et al.). Also useful are the vinyl carbazole polymers described in copending and commonly assigned U.S. Pat. No. 7,175,949 (Tao et al.). Copolymers of polyethylene glycol methacrylate/acrylonitrile/styrene in particulate form, dissolved copolymers derived from carboxyphenyl methacrylamide/acrylonitrile/methacrylamide/N-phenyl maleimide, copolymers derived from polyethylene glycol methacrylate/acrylonitrile/vinylcarbazole/-styrene/methylacrylic acid, copolymers derived from N-phenyl maleimide/methacrylamide/methacrylic acid, copolymers derived from urethane-acrylic intermediate A (the reaction product of p-toluene sulfonyl isocyanate and hydroxylethyl methacrylate)/acrylonitrile/N-phenyl maleimide, and copolymers derived from N-methoxymethyl methacrylamide/methacrylic acid/acrylonitrile/n-phenylmaleimide are useful.

Other useful polymeric binders are particulate poly(urethane-acrylic) hybrids that are distributed (usually uniformly) throughout the imageable layer. Each of these hybrids has a molecular weight of from about 50,000 to about 500,000 and the particles have an average particle size of from about 10 to about 10,000 nm (typically from about 30 to about 500 nm and or from about 30 to about 150 nm). These hybrids can be either “aromatic” or “aliphatic” in nature depending upon the specific reactants used in their manufacture. Blends of particles of two or more poly(urethane-acrylic) hybrids can also be used. For example, a blend of Hybridur® 570 polymer dispersion with Hybridur® 870 polymer dispersion could be used.

Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of polyurethane-acrylic) hybrid particles. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents. Further details about commercial Hybridur® polymer dispersions can be obtained by visiting the Air Products and Chemicals, Inc. website.

The radiation-sensitive composition and imageable layer can further comprise one or more phosphate (meth)acrylates, each of which has a molecular weight generally greater than 200 and typically at least 300 and up to and including 1000. By “phosphate (meth)acrylate” we also mean to include “phosphate methacrylates” and other derivatives having substituents on the vinyl group in the acrylate moiety.

Each phosphate moiety is typically connected to an acrylate moiety by an aliphatic chain [that is, an -(aliphatic-O)-chain] such as an alkyleneoxy chain [that is an -(alkylene-O)ₘ-chain] composed of at least one alkyleneoxy unit, in which the alkylene moiety has 2 to 6 carbon atoms and can be either linear or branched and m is 1 to 10. For example, the alkyleneoxy chain can comprise ethyleneoxy units, and m is from 2 to 8 or m is from 3 to 6. The alkyleneoxy chains in a specific compound can be the same or different in length and have the same or different alkylene group. Representative phosphate (meth)acrylates useful in this invention are described for example, in U.S. Pat. No. 7,175,969 (Ray et al.). The phosphate acrylate can be present in an amount of at least 0.5 and up to and including 20% and typically at least 0.9 and up to and including 10%, by weight of the total solids.

The radiation-sensitive composition and imageable layer can further comprise one or more trialkoxysilylalkyl (meth)acrylates or vinyl trialkoxysilanes, each of which has a molecular weight generally greater than 120 and typically at least 145 and up to and including 1,000.

The radiation-sensitive composition (and imageable layer) can also include a “primary additive” that is a poly(alkylene glycol) or an ether or ester thereof that has a molecular weight of at least 200 and up to and including 4000. This primary additive is present in an amount of at least 2 and up to and including 50 weight %, based on the total dry weight. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate. Also useful are SR9036 (ethoxylated (30) bisphenol A dimethacrylate), CD9038 (ethoxylated (30) bisphenol A diacrylate), and SR494 (ethoxylated (5) pentaerythritol tetraacrylate), and similar compounds all of which can be obtained from Sartomer Company, Inc. In some embodiments, the primary additive may be “non-reactive” meaning that it does not contain polymerizable vinyl groups.

The radiation-sensitive composition (and imageable layer) can also include a “secondary additive” that is a poly(vinyl alcohol), a poly(vinyl pyrrolidone), poly(vinyl imidazole), or polyester in an amount of up to and including 20 weight % based on the total dry weight.

The radiation-sensitive composition (and imageable layer) can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

The radiation-sensitive composition that is sensitive to UV/violet radiation may include one or more thermopolymerization inhibitors such as those described on page 10 (lines 14-22) of WO 2004/074929 (noted above).

The negative-working imageable elements can be formed by suitable application of a radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition that is directly applied to the substrate without any intermediate layer.

In some embodiments, the element may include what is conventionally known as an overcoat (also known as an “oxygen impermeable topcoat” or “oxygen barrier layer”) disposed over the imageable layer, for example, as described in EP Patent Publications 1,788,429, 1,788,431 and 1,788,434 and U.S. Patent Application Publication 2005/0266349. Such overcoat layers comprise a poly(vinyl alcohol) or poly(vinyl pyrrolidone) as the predominant polymeric binder. If present, the overcoat is the outermost layer of the imageable element.

A radiation-sensitive composition containing the components described above can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder).

Illustrative of such manufacturing methods is mixing the free radically polymerizable component, polymeric binder(s), initiator composition, radiation absorbing compound, colorant pigment, dye, and any other components of the radiation-sensitive composition in a suitable coating solvent including water, organic solvents [such as those mentioned above in describing the solubility of the pigment colorants, including but not limited to glycol ethers including 1-methoxypropan-2-ol, methyl ethyl ketone (2-butanone), methanol, ethanol, 1-methoxy-2-propanol, iso-propyl alcohol, acetone, γ-butyrolactone, n-propanol, and tetrahydrofuran], or mixtures thereof, applying the resulting solution to a substrate, and removing the solvent(s) by evaporation under suitable drying conditions. Some representative coating solvents and negative-working imageable layer formulations are described in the Examples below. After proper drying, the coating weight of the imageable layer is generally at least 0.1 and up to and including 5 g/m² or at least 0.5 and up to and including 3.5 g/m².

Once the imageable layer formulation has been applied and dried on the substrate, and any overcoat formulation has been applied and dried, the imageable element can be enclosed in water-impermeable material that substantially inhibits the transfer of moisture to and from the imageable element.

By “enclosed”, we mean that the imageable element is wrapped, encased, enveloped, or contained in a manner such that both upper and lower surfaces and all edges are within the water-impermeable sheet material. Thus, none of the imageable element is exposed to the environment once it is enclosed. Further details of this process of single or stacks of imageable elements are provided in U.S. Pat. No. 7,175,969 (noted above).

Positive-Working Imageable Elements

The imageable elements processed using the invention can also be single- or multi-layer, thermally-sensitive, positive-working imageable elements that generally rely on a radiation absorbing compound dispersed within one or more polymeric binders that, upon suitable irradiation, are soluble, dispersible, or removable in processing solutions including alkaline developers. Thus, the imageable layer, upon irradiation, undergoes a change in solubility properties with respect to the processing solution in its irradiated (exposed) regions.

For example, “single-layer” positive-working imageable elements are described for example, in WO 2004/081662 (Memetea et al.), U.S. Pat. Nos. 6,255,033 (Levanon et al.), 6,280,899 (Hoare et al.), 6,485,890 (Hoare et al.), 6,558,869 (Hearson et al.), 6,706,466 (Parsons et al.), 6,541,181 (Levanon et al.), 7,223,506 (Kitson et al.), 7,247,418 (Saraiya et al.), 7,270,930 (Hauck et al.), 7,279,263 (Goodin), and 7,399,576 (Levanon), EP 1,627,732 (Hatanaka et al.), and U.S. Published Patent Applications 2005/0214677 (Nagashima), 2004/0013965 (Memetea et al.), 2005/0003296 (Memetea et al.), and 2005/0214678 (Nagashima).

In general, single-layer imageable elements are formed by suitable application of an imageable layer formulation containing one or more polymeric binders and the discrete particles to a suitable substrate (described above) to form an imageable layer. The substrate can be treated to provide an “interlayer” for improved adhesion or hydrophilicity, and the single imageable layer is applied over the interlayer.

The single-layer, positive-working imageable element also includes one or more radiation absorbing compounds (described above). While these compounds can be sensitive to any suitable energy form (including UV or visible radiation), they are usually sensitive to near-infrared or infrared radiation and thus, the radiation absorbing compounds having spectral sensitivity to from about 700 to about 1400 nm and typically from about 700 to about 1200 nm. Examples of suitable infrared radiation-sensitive compounds, including IR dyes are described above in relation to the negative-working imageable elements.

The radiation absorbing compound is generally present in the imageable element in an amount sufficient to render the imageable layer insoluble to an aqueous developer after exposure to appropriate radiation. This amount is generally at least 0.5% and up to 30 weight % and typically from about 3 to about 10 weight % (based on total dry layer weight). In most embodiments, the radiation absorbing compound is present in the single imageable layer. Alternatively or additionally, radiation absorbing compounds may be located in a separate layer that is in thermal contact with the single imageable layer. Thus, during imaging, the action of the radiation absorbing compound can be transferred to the single imageable layer without the compound originally being incorporated into it.

In addition, solubility-suppressing components are optionally incorporated into the single imageable layer. Such components act as dissolution inhibitors that function as solubility-suppressing components for the polymeric binders. Dissolution inhibitors typically have polar functional groups that are believed to act as acceptor sites for hydrogen bonding with various groups in the polymeric binders. The acceptor sites comprise atoms with high electron density, and can be selected from electronegative first row elements such as carbon, nitrogen, and oxygen. Dissolution inhibitors that are soluble in the alkaline developer are useful. Useful polar groups for dissolution inhibitors include but are not limited to, ether groups, amine groups, azo groups, nitro groups, ferrocenium groups, sulfoxide groups, sulfone groups, diazo groups, diazonium groups, keto groups, sulfonic acid ester groups, phosphate ester groups, triarylmethane groups, onium groups (such as sulfonium, iodonium, and phosphonium groups), groups in which a nitrogen atom is incorporated into a heterocyclic ring, and groups that contain a positively charged atom (such as quaternized ammonium group). Compounds that contain a positively-charged nitrogen atom useful as dissolution inhibitors include, for example, tetraalkyl ammonium compounds and quaternized heterocyclic compounds such as quinolinium compounds, benzothiazolium compounds, pyridinium compounds, and imidazolium compounds. Further details and representative compounds useful as dissolution inhibitors are described for example in U.S. Pat. No. 6,294,311 (noted above). Useful dissolution inhibitors include triarylmethane dyes such as ethyl violet, crystal violet, malachite green, brilliant green, Victoria blue B, Victoria blue R, and Victoria pure blue BO, BASONYL® Violet 610 and D11 (PCAS, Longjumeau, France). Thus, some of the soluble dyes described above can also function as dissolution inhibitors in the imageable elements.

The polymeric binders used in the imageable layer are generally soluble in alkaline developers (defined below) after thermal imaging. The polymer(s) are present in an amount of at least 10 weight % and typically from about 20 to about 80 weight % of the total dry imageable layer weight.

Useful polymeric binders can be poly(vinyl phenols) or derivatives thereof, or phenolic polymers. They may include carboxylic (carboxy), sulfonic (sulfo), phosphonic (phosphono), or phosphoric acid groups that are incorporated into the polymer molecule. Other useful additional polymers include but are not limited to, novolak resins, resole resins, poly(vinyl acetals) having pendant phenolic groups, and mixtures of any of these resins (such as mixtures of one or more novolak resins and one or more resole resins). Typical novolak resins include but are not limited to, phenol-formaldehyde resins, cresol-formaldehyde resins, phenol-cresol-formaldehyde resins, p-t-butylphenol-formaldehyde resins, and pyrogallol-acetone resins, such as novolak resins prepared from reacting m-cresol or a m,p-cresol mixture with formaldehyde using conventional conditions. For example, some useful novolak resins include but are not limited to, xylenol-cresol resins, for example, SPN400, SPN420, SPN460, and VPN1100 (that are available from AZ Electronics) and EP25D40G and EP25D50G (noted below for the Examples) that have higher molecular weights, such as at least 4,000.

Other useful additional resins include polyvinyl compounds having phenolic hydroxyl groups, include poly(hydroxystyrenes) and copolymers containing recurring units of a hydroxystyrene and polymers and copolymers containing recurring units of substituted hydroxystyrenes. Also useful are branched poly(hydroxystyrenes) having multiple branched hydroxystyrene recurring units derived from 4-hydroxystyrene as described for example in U.S. Pat. Nos. 5,554,719 (Sounik) and 6,551,738 (Ohsawa et al.), and U.S. Published Patent Applications 2003/0050191 (Bhatt et al.) and 2005/0051053 (Wisnudel et al.), and in copending and commonly assigned U.S. Patent Application Publication 2008/0008956 (Levanon et al.). For example, such branched hydroxystyrene polymers comprise recurring units derived from a hydroxystyrene, such as from 4-hydroxystyrene, which recurring units are further substituted with repeating hydroxystyrene units (such as 4-hydroxystyrene units) positioned ortho to the hydroxy group.

One group of useful polymeric binders are poly(vinyl phenol) and derivatives thereof. Such polymers are obtained generally by polymerization of vinyl phenol monomers, that is, substituted or unsubstituted vinyl phenols. Substituted vinyl phenol recurring units include those described below for the “a” recurring units in Structure (I). Some vinyl phenol copolymers are described in EP 1,669,803A (Barclay et al.).

Other useful polymeric binders are modified novolak or resole resins that are represented by Structure (POLYMER):

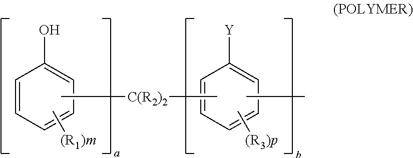

wherein

### Y is

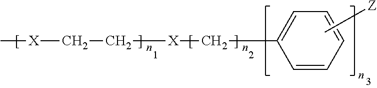

a is from about 90 to about 99 mol % (typically from about 92 to about 98 mol %), b is from about 1 to about 10 mol % (typically from about 2 to about 8 mol %), R₁ and R₃ are independently hydrogen or hydroxy, alkyl, or alkoxy groups, R₂ is hydrogen or an alkyl group, X is an alkylene, oxy, thio, —OC(═O)Ar—, —OC(═O)CH═CH—, or —OCO(CH₂)ₙ₄— group wherein Ar is an aryl group, m and p are independently 1 or 2, n₃ is 0 or an integer up to 5 (for example 0, 1, 2, or 3), n₂ is 0 or an integer up to 5 (for example, 0, 1, or 2), n₃ is 0 or 1 (typically 0), n₄ is at least 1 (for example, up to 8), and Z is —C(═O)OH, —S(═O)₂OH, —P(═O)(OH)₂, or —OP(═O)(OH)₂.

The alkyl and alkoxy groups present in the primary polymeric binders (for R¹, R², and R³) can be unsubstituted or substituted with one or more halo, nitro, or alkoxy groups, and can have 1 to 3 carbon atoms. Such groups can be linear, branched, or cyclic (that is, “alkyl” also include “cycloalkyl” for purposes of this invention).

When X is alkylene, it can have 1 to 4 carbon atoms and be further substituted similarly to the alkyl and alkoxy groups. In addition, the alkylene group can be a substituted or unsubstituted cycloalkylene group having at least 5 carbon atoms in the ring and chain. Ar is a substituted or unsubstituted, 6 or 10-membered carbocyclic aromatic group such as substituted or unsubstituted phenyl and naphthyl groups. Typically, Ar is an unsubstituted phenyl group.

Other polymeric binders that may be in the imageable layer include phenolic resins such as novolak and resole resins, and such resins can also include one or more pendant diazo, carboxylate ester, phosphate ester, sulfonate ester, sulfonate ester, or ether groups. The hydroxy groups of the phenolic resins can be converted to -T-Z groups in which T represents a polar group and Z represents a non-diazide functional group as described for example in U.S. Pat. No. 6,218,083 (McCullough et al.) and WO 99/001795 (McCullough et al.). The hydroxy groups can also be derivatized with diazo groups containing o-naphthoquinone diazide moieties as described for example in U.S. Pat. Nos. 5,705,308 (West et al.) and 5,705,322 (West et al.). Other useful secondary binder resins include acrylate copolymers as described for example in EP 737,896A (Ishizuka et al.), cellulose esters and polyvinyl acetals) as described for example in U.S. Pat. No. 6,391,524 (Yates et al.), DE 10 239 505 (Timpe et al.), and WO 2004081662 (Memetea et al.).

The polymeric binder can be present in the imageable layer at a dry coverage of from about 15 to 100 weight % (typically from about 30 to about 95 weight %) based on the total dry imageable layer weight.

The single imageable layer can further include a variety of additives including dispersing agents, humectants, biocides, plasticizers, surfactants for coatability or other properties, viscosity builders, pH adjusters, drying agents, defoamers, preservatives, antioxidants, development aids, rheology modifiers, or combinations thereof, or any other addenda commonly used in the lithographic art, in conventional amounts.

The single-layer imageable element can be prepared by applying the layer formulation over the surface of the substrate (and any other hydrophilic layers provided thereon) using conventional coating or lamination methods. Thus, the formulations can be applied by dispersing or dissolving the desired ingredients in a suitable coating solvent, and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support (such as an on-press printing cylinder or printing sleeve).

The coating weight for the single imageable layer can be from about 0.5 to about 2.5 g/m² and typically from about 1 to about 2 g/m².

The selection of solvents used to coat the imageable layer formulation depends upon the nature of the polymeric materials and other components in the formulations. Generally, the imageable layer formulation is coated out of acetone, methyl ethyl ketone, or another ketone, tetrahydrofuran, 1-methoxypropan-2-ol, 1-methoxy-2-propyl acetate, and mixtures thereof using conditions and techniques well known in the art.

Alternatively, the layer(s) may be applied by conventional extrusion coating methods from melt mixtures of the respective layer compositions. Typically, such melt mixtures contain no volatile organic solvents.

Intermediate drying steps may be used between applications of the various layer formulations to remove solvent(s) before coating other formulations. Drying steps may also help in preventing the mixing of the various layers.

Other imageable elements that comprise an aluminum-containing substrate (described above), an inner layer (also known as an “underlayer”), and an ink-receptive outer layer (also known as a “top layer” or “topcoat”) disposed over the inner layer. Before thermal imaging, the outer layer is generally not soluble, dispersible, or removable by the processing solution within the usual time allotted for development, but after thermal imaging, the imaged regions of the outer layer are more readily removable by or dissolvable in the processing solution. The inner layer is also generally removable by the processing solution. An infrared radiation absorbing compound (defined below) is also present in the imageable element, and is typically present in the inner layer but may optionally be in a separate layer between the inner and outer layers.

Thermally imageable, multi-layer elements are described, for example, in U.S. Pat. Nos. 6,294,311 (Shimazu et al.), 6,352,812 (Shimazu et al.), 6,593,055 (Shimazu et al.), 6,352,811 (Patel et al.), 6,358,669 (Savariar-Hauck et al.), 6,528,228 (Savariar-Hauck et al.), 7,163,770 (Saraiya et al.), 7,163,777 (Ray et al.), 7,186,482 (Kitson et al.), 7,223,506 (noted above), 7,229,744 (Patel), 7,241,556 (Saraiya et al.), 7,247,418 (noted above), 7,291,440 (Ray et al.), 7,300,726 (Patel et al.), and 7,338,745 (Ray et al.), U.S. Patent Application Publications 2004/0067432 A1 (Kitson et al.) and 2005/0037280 (Loccufier et al.).

The inner layer is disposed between the outer layer and the substrate. Typically, it is disposed directly on the substrate. The inner layer comprises a predominant first polymeric material that is removable by the processing composition and preferably soluble in that solution to reduce sludging. In addition, this first polymeric material is preferably insoluble in the solvent used to coat the outer layer so that the outer layer can be coated over the inner layer without dissolving the inner layer. Mixtures of these first polymeric binders can be used if desired in the inner layer.

Useful first polymeric binders for the inner layer include but are not limited to, (meth)acrylonitrile polymers, (meth)acrylic resins comprising pendant carboxy groups, polyvinyl acetals, maleated wood rosins, styrene-maleic anhydride copolymers, (meth)acrylamide polymers such as polymers derived from N-alkoxyalkyl methacrylamide, polymers derived from an N-substituted cyclic imide, polymers having pendant urea or cyclic urea groups, and combinations thereof. First polymeric binders that provide resistance both to fountain solution and aggressive washes are disclosed in U.S. Pat. No. 6,294,311 (noted above).

Useful first polymeric binders include (meth)acrylonitrile polymers, and polymers derived from an N-substituted cyclic imide (especially N-phenylmaleimide), a (meth)acrylamide (especially methacrylamide), a monomer having a pendant urea or cyclic urea group, and a (meth)acrylic acid (especially methacrylic acid). First polymeric binders of this type are copolymers that comprise from about 20 to about 75 mol % of recurring units derived from N-phenylmaleimide, N-cyclohexylmaleimide, N-(4-carboxyphenyl)maleimide, N-benzylmaleimide, or a mixture thereof, from about 10 to about 50 mol % of recurring units derived from acrylamide, methacrylamide, or a mixture thereof, and from about 5 to about 30 mol % of recurring units derived from methacrylic acid. Other hydrophilic monomers, such as hydroxyethyl methacrylate, may be used in place of some or all of the methacrylamide. Other alkaline soluble monomers, such as acrylic acid, may be used in place of some or all of the methacrylic acid. Optionally, these polymers can also include recurring units derived from (meth)acrylonitrile or N-[2-(2-oxo-1-imidazolidinypethyl]-methacrylamide.

Other useful first polymeric binders can comprise, in polymerized form, from about 5 mol % to about 30 mol % of recurring units derived from an ethylenically unsaturated polymerizable monomer having a carboxy group (such as acrylic acid, methacrylic acid, itaconic acid, and other similar monomers known in the art (acrylic acid and methacrylic acid are preferred), from about 20 mol % to about 75 mol % of recurring units derived from N-phenylmaleimide, N-cyclohexylmaleimide, or a mixture thereof, optionally, from about 5 mol % to about 50 mol % of recurring units derived from methacrylamide, and from about 3 mol % to about 50 mol % of one or more recurring units derived from monomer compounds of the following Structure (I):

CH₂═C(R₂)—C(═O)—NH—CH₂—OR₁ (I)

wherein R₁ is a C₁ to C₁₂ alkyl, phenyl, C₁ to C₁₂ substituted phenyl, C₁ to C₁₂ aralkyl, or Si(CH₃)₃, and R₂ is hydrogen or methyl. Methods of preparation of certain of these polymeric materials are disclosed in U.S. Pat. No. 6,475,692 (Jarek).

Additional useful polymeric binders for the inner layer are described for example, in U.S. Pat. Nos. 7,144,661 (Ray et al.), 7,163,777 (Ray et al.), and 7,223,506 (Kitson et al.), and U.S. Patent Application Publications 2006/0257764 (Ray et al.) and 2007/0172747 (Ray et al.).

In some embodiments, the inner layer (and typically only the inner layer) further comprises an infrared radiation absorbing compound (“IR absorbing compounds”) that absorbs radiation from about at 600 nm to about 1500 and typically from about at 700 nm to about 1400 nm, with minimal absorption at from about 300 to about 600 nm. This compound (sometimes known as a “photothermal conversion material”) absorbs radiation and converts it to heat. Although one of the polymeric materials may itself comprise an IR absorbing moiety, typically the infrared radiation absorbing compound is a separate compound. This compound may be either a dye or pigments such as iron oxides and carbon blacks. Examples of useful pigments are ProJet 900, ProJet 860 and ProJet 830 (all available from the Zeneca Corporation).

Useful infrared radiation absorbing compounds also include carbon blacks including carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful.

IR absorbing dyes (especially those that are soluble in an alkaline developer) are desired to prevent sludging of the developer by insoluble material. Examples of suitable IR dyes include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indoaniline dyes, merostyryl dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in numerous publications including U.S. Pat. Nos. 6,294,311 (noted above), 5,208,135 (Patel et al.), 6,153,356 (Urano et al.), 6,264,920 (Achilefu et al.), 6,309,792 (Hauck et al.), and 6,787,281 (Tao et al.), and EP 1,182,033A2 (noted above).

A general description of one class of suitable cyanine dyes is shown by the formula in paragraph [0026] of WO 2004/101280 (Munnelly et al.).

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (Hauck et al.), 6,264,920 (Achilefu et al.), 6,153,356 (Urano et al.), 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Examples of useful IR absorbing compounds include ADS-830A and ADS-1064 (American Dye Source, Baie D'Urfe, Quebec, Canada), EC2117 (FEW, Wolfen, Germany), Cyasorb® IR 99 and Cyasorb® IR 165 (GPTGlendale Inc. Lakeland, Fla.), and IR Absorbing Dye A used in the Examples below.

The infrared radiation absorbing compound can be present in the imageable element in an amount of generally from about 5% to about 30% and typically from about 12 to about 25%, based on the total dry weight of the element. This amount is based on the total dry weight of the layer in which it is located.

The inner layer can include other components such as surfactants, dispersing aids, humectants, biocides, viscosity builders, drying agents, defoamers, preservatives, antioxidants, colorants, or organic or inorganic particles.

The inner layer generally has a dry coating coverage of from about 0.5 to about 2.5 g/m² and typically from about 1 to about 2 g/m². The total polymeric binders described above generally comprise at least 50 weight % and typically from about 60 to about 90 weight % based on the total dry layer weight, and this amount can be varied depending upon what other polymers and chemical components are present.

The ink-receptive outer layer of the imageable element is disposed over the inner layer and in typical embodiments there are no intermediate layers between the inner and outer layers. The outer layer comprises a polymeric material that is different than the first polymeric binder described above. The outer layer is substantially free of infrared radiation absorbing compounds, meaning that none of these compounds are purposely incorporated therein and insubstantial amounts diffuse into it from other layers.

Thus, the outer layer comprises a polymeric binder that is a light-stable, water-insoluble, alkaline developer soluble, film-forming binder material such as phenolic resins, urethane resins, and polyacrylates. Particularly useful binder materials are described, for example in U.S. Pat. Nos. 6,352,812 (noted above), 6,358,669 (noted above), 6,352,811 (noted above), 6,294,311 (noted above), 6,893,783 (Kitson et al.), and 6,645,689 (Jarek), U.S. Patent Application Publications 2003/0108817 (Patel et al) and 2003/0162126 (Kitson et al.), and WO 2005/018934 (Kitson et al.).

Other useful film-forming polymeric binders for the outer layer are phenolic resins or hydroxy-containing polymers containing phenolic monomeric units that can be random, alternating, block, or graft copolymers of different monomers and may be selected from polymers of vinyl phenol, novolak resins, or resole resins.

Useful polyvinyl phenol) resins can be polymers of one or more hydroxyphenyl containing monomers such as hydroxystyrenes and hydroxyphenyl (meth)acrylates. Other monomers not containing hydroxy groups can be copolymerized with the hydroxy-containing monomers. These resins can be prepared by polymerizing one or more of the monomers in the presence of a radical initiator or a cationic polymerization initiator using known reaction conditions.

Examples of useful hydroxy-containing polymers include ALNOVOL SPN452, SPN400, HPN100 (Clariant GmbH), DURITE PD443, SD423A, SD126A, PD494A, PD-140 (Hexion Specialty Chemicals, Columbus, Ohio), BAKELITE 6866LB02, AG, 6866LB03 (Bakelite AG), KR 400/8 (Koyo Chemicals Inc.), HRJ 1085 and 2606 (Schenectady International, Inc.), and Lyncur CMM (Siber Hegner), all of which are described in U.S. Patent Application Publication 2005/0037280 (noted above).

Useful novolak resins in the upper layer can be non-functionalized, or functionalized with polar groups including but not limited to, diazo groups, carboxylic acid esters (such as acetate benzoate), phosphate esters, sulfonate esters, sulfonate esters (such as methyl sulfonate, phenyl sulfonate, tosylate, 2-nitrobenzene tosylate, and p-bromophenyl sulfonate), and ethers (such as phenyl ethers). The phenolic hydroxyl groups can be converted to -T-Z groups in which “T” is a polar group and “Z” is another non-diazide functional group (as described for example in WO 99/01795 of McCullough et al. and U.S. Pat. No. 6,218,083 of McCullough et al.). The phenolic hydroxyl groups can also be derivatized with diazo groups containing o-naphthoquinone diazide moieties (as described for example in U.S. Pat. Nos. 5,705,308 and 5,705,322 both of West et al.).

Useful polymeric binders in the outer layer include copolymers comprising recurring units derived from styrene or a styrene derivative and recurring units derived from maleic anhydride, copolymers comprising recurring units derived from a (meth)acrylate and recurring units derived from a (meth)acrylic acid, or mixtures of both types of copolymers. Further details of these types of copolymers are described in U.S. Patent Application Publication 2007/0065737 (Kitson et al.).

The outer layer can also include non-phenolic polymeric materials as film-forming binder materials in addition to or instead of the phenolic resins described above. Such non-phenolic polymeric materials include polymers formed from maleic anhydride and one or more styrenic monomers (that is styrene and styrene derivatives having various substituents on the benzene ring), polymers formed from methyl methacrylate and one or more carboxy-containing monomers, and mixtures thereof. These polymers can comprises recurring units derived from the noted monomers as well as recurring units derived from additional, but optional monomers [such as (meth)acrylates, (meth)acrylonitriles and (meth)acrylamides].

In some embodiments, the outer layer may further include a monomeric or polymeric compound that includes a benzoquinone diazide and/or naphthoquinone diazide moiety. The polymeric compounds can be phenolic resins derivatized with a benzoquinone diazide and/or naphthoquinone diazide moiety as described for example in U.S. Pat. Nos. 5,705,308 (West et al.) and 5,705,322 (West et al.). Mixtures of such compounds can also be used. An example of a useful polymeric compound of this type is P-3000, a naphthoquinone diazide of a pyrogallol/acetone resin (available from PCAS, France). Other useful compounds containing diazide moieties are described for example in U.S. Pat. Nos. 6,294,311 (noted above) and 5,143,816 (Mizutani et al.).

The outer layer generally has a dry coating coverage of from about 0.2 to about 2 g/m² and typically from about 0.4 to about 1.5 g/m².

There may be a separate layer that is between and in contact with the inner and outer layers. This separate layer can act as a barrier to minimize migration of radiation absorbing compound(s) from the inner layer to the outer layer. This separate “barrier” layer generally comprises other polymeric binders that are soluble in the alkaline developer. If this polymeric binder is different from the first polymeric binder(s) in the inner layer, it is typically soluble in at least one organic solvent in which the inner layer first polymeric binders are insoluble. A useful polymeric binder is a poly(vinyl alcohol). Generally, this barrier layer should be less than one-fifth as thick as the inner layer, and typically less than one-tenth as thick as the inner layer.

Alternatively, there may be a separate layer between the inner and outer layers that contains the infrared radiation absorbing compound(s), which may also be present in the inner layer, or solely in the separate layer.

The multi-layer imageable element can be prepared by sequentially applying an inner layer formulation over the surface of the hydrophilic substrate (and any other hydrophilic layers provided thereon), and then applying an outer layer formulation over the inner layer using conventional coating or lamination methods. It is important to avoid intermixing of the inner and outer layer formulations.

The inner and outer layers can be applied by dispersing or dissolving the desired ingredients in a suitable coating solvent, and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support.

The selection of solvents used to coat both the inner and outer layers depends upon the nature of the first and second polymeric binders, other polymeric materials, and other components in the formulations. To prevent the inner and outer layer formulations from mixing or the inner layer from dissolving when the outer layer formulation is applied, the outer layer formulation should be coated from a solvent in which the first polymeric binder(s) of the inner layer are insoluble.

Generally, the inner layer formulation is coated out of a solvent mixture of methyl ethyl ketone (MEK), 1-methoxy-2-propyl acetate (PMA), γ-butyrolactone (BLO), and water, a mixture of MEK, BLO, water, and 1-methoxypropan-2-ol (also known as Dowanol® PM or PGME), a mixture of diethyl ketone (DEK), water, methyl lactate, and BLO, a mixture of DEK, water, and methyl lactate, or a mixture of methyl lactate, methanol, and dioxolane.

The outer layer formulation can be coated out of solvents or solvent mixtures that do not dissolve the inner layer. Typical solvents for this purpose include but are not limited to, butyl acetate, iso-butyl acetate, methyl iso-butyl ketone, DEK, 1-methoxy-2-propyl acetate (PMA), iso-propyl alcohol, PGME and mixtures thereof. Particularly useful is a mixture of DEK and PMA, or a mixture of DEK, PMA, and isopropyl alcohol.

Alternatively, the inner and outer layers may be applied by extrusion coating methods from melt mixtures of the respective layer compositions. Typically, such melt mixtures contain no volatile organic solvents.

Intermediate drying steps may be used between applications of the various layer formulations to remove solvent(s) before coating other formulations. Drying steps may also help in preventing the mixing of the various layers.

After drying the layers, the element can be further “conditioned” with a heat treatment at from about 40 to about 90° C. for at least 4 hours (for example, at least 20 hours) under conditions that inhibit the removal of moisture from the dried layers. For example, the heat treatment is carried out at from about 50 to about 70° C. for at least 24 hours. During the heat treatment, the imageable element is wrapped or encased in a water-impermeable sheet material to represent an effective barrier to moisture removal from the precursor, or the heat treatment of the imageable element is carried out in an environment in which relative humidity is controlled to at least 25%. In addition, the water-impermeable sheet material can be sealed around the edges of the imageable element, with the water-impermeable sheet material being a polymeric film or metal foil that is sealed around the edges of the imageable element.

In some embodiments, this heat treatment can be carried out with a stack comprising at least 100 of the same imageable elements, or when the imageable element is in the form of a coil or web. When conditioned in a stack, the individual imageable elements may be separated by suitable interleaving papers. Such papers are available from several commercial sources. The interleaving papers may be kept between the imageable elements after conditioning during packing, shipping, and use by the customer.

### Imaging Conditions

The imageable elements can have any useful form and size or shape including but not limited to, printing plate precursors, printing cylinders, printing sleeves (both hollow or solid), and printing tapes (including flexible printing webs).

During use, the positive-working and negative-working imageable elements of this invention are exposed to a suitable source of imaging or exposing radiation at a wavelength of from about 150 to about 1500 nm. For example, imaging can be carried out using imaging or exposing radiation, such as from an infrared laser at a wavelength of at least 750 nm and up to and including about 1400 nm and typically at least 700 nm and up to and including 1200 nm. Imaging can be carried out using imaging radiation at multiple wavelengths at the same time if desired. Other imageable elements, especially negative-working imageable elements can be exposed to a suitable source of UV, “violet”, or visible imaging radiation.

Thus, in some embodiments of the method of this invention, the imageable element can have a spectral sensitivity to imagewise exposure that is carried out at a wavelength of from about 250 to about 475 nm, or to imagewise exposure that is carried out at a wavelength of from about 750 to about 1250 nm.

The laser used to expose the imageable element is usually a diode laser, because of the reliability and low maintenance of diode laser systems, but other lasers such as gas or solid-state lasers may also be used. The combination of power, intensity and exposure time for laser imaging would be readily apparent to one skilled in the art.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful near-infrared and infrared imaging apparatus is available as models of Creo Trendsetter or Creo Quantum 800 imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging with infrared radiation can be carried out generally at imaging energies of at least 30 mJ/cm² and up to and including 500 mJ/cm², and typically at least 50 and up to and including 300 mJ/cm² depending upon the sensitivity of the imageable layer.

Useful UV and “violet” imaging apparatus include Prosetter (from Heidelberger Druckmaschinen, Germany), Luxel V-8 (from FUJI, Japan), Python (Highwater, UK), MakoNews, Mako 2, Mako 4 or Mako 8 (from ECRM, US), Micra (from Screen, Japan), Polaris and Advantage (from AGFA, Belgium), Laserjet (from Krause, Germany), and Andromeda® A750M (from Lithotech, Germany), imagesetters.

Imaging radiation in the UV to visible region of the spectrum, and particularly the UV region (for example at least 250 nm and up to and including 450 nm), can be carried out generally using energies of at least 0.01 mJ/cm² and up to and including 0.5 mJ/cm², and typically at least 0.02 and up to and including about 0.1 mJ/cm². It would be desirable, for example, to image the UV/visible radiation-sensitive imageable elements at a power density in the range of at least 0.5 and up to and including 50 kW/cm² and typically of at least 5 and up to and including 30 kW/cm².

After imaging of negative-working imageable elements, a heating step might be used to accelerate the formation of a latent image. This heating step can be realized in so called “preheat units” that can be a separate machine or integrated into the processor that develops the imaged element. There are different types of preheat units. The most common ones use infrared radiation or hot air circulation, or combination thereof, to heat the imaged element. The temperature used for the purpose is from about 70 to about 200° C. and typically from about 90 to about 160° C.

Before developing the imaged element, a pre-rinse step might be carried out especially for the negative-working elements having a protective oxygen barrier or topcoat. This pre-rinse step can be carried out in a stand-alone apparatus or by manually rinsing the imaged element with water or the pre-rinse step can be carried out in a washing unit that is integrated in a processor used for developing the imaged element. For the free radical generating radiation-sensitive compositions and imageable elements, both the preheat unit and the pre-rinse unit are usually integrated into the processor used for developing the imaged element.

### Development and Printing

With or without the need for a preheat step after imaging, the imaged elements can be developed “off-press” using conventional processing and an aqueous processing solution such as an aqueous developer.

As one skilled in the art would understand, the best developers for negative-working imaging elements of this invention will likely be different than the best developers for the single- or multi-layer positive imageable elements. A skilled worker would be able to determine from the level of skill and teaching in the art which developers are best with a given type of imageable element of this invention.

The processing solutions generally include surfactants, chelating agents (such as salts of ethylenediaminetetraacetic acid), organic solvents (such as benzyl alcohol), and alkaline components (such as inorganic metasilicates, organic metasilicates, hydroxides, and bicarbonates). The pH of such solutions is generally from about 4 to about 14. Aqueous alkaline developers and organic solvent-containing alkaline developers can be used.

Organic solvent-containing alkaline developers are generally single-phase solutions of one or more organic solvents that are miscible with water, and generally have a pH below 12. Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. The organic solvent(s) is generally present in an amount of from about 0.5 to about 15% based on total developer weight.

Representative organic solvent-containing alkaline developers include ND-1 Developer, 955 Developer, 956 Developer, 989 Developer, Developer 980, and 956 Developer (available from Eastman Kodak Company), HDN-1 Developer and LP-DS Developer (available from Fuji Photo), and EN 232 Developer and PL10 Developer (available from Agfa).

Useful aqueous alkaline developers generally have a pH of at least 7 and preferably of at least 11 and up to 13.5. Such developers include but are note limited to, 3000 Developer, 9000 Developer, Goldstar® Developer, Goldstar® Plus Developer, Goldstar® Premium Developer, GREENSTAR Developer, ThermalPro Developer, PROTHERM Developer, MX1813 Developer, and MX1710 Developer (all available from Eastman Kodak Company), as well as Fuji HDP7 Developer (Fuji Photo), and Energy CTP Developer (Agfa). These compositions also generally include surfactants, chelating agents (such as salts of ethylenediaminetetraacetic acid), and alkaline components (such as inorganic metasilicates, organic metasilicates, hydroxides, and bicarbonates).

Such alkaline developers can also include one or more “coating-attack suppressing agents” that are developer-soluble compounds that suppress developer attack of the outer layer. “Developer-soluble” means that enough of the agent(s) will dissolve in the developer to suppress attack by the developer. Mixtures of these compounds can be used. Typically, the coating-attack suppressing agents are developer-soluble polyethoxylated, polypropoxylated, or polybutoxylated compounds that include recurring —(CH₂—CHRₐ—O—)— units in which Rₐ is hydrogen or a methyl or ethyl group. Each agent can have the same or different recurring units (in a random or block fashion). Representative compounds of this type include but are not limited to, polyglycols and polycondensation products having the noted recurring units. Examples of such compounds and representative sources, tradenames, or methods of preparing are described for example in U.S. Pat. No. 6,649,324 (Fiebag et al.).

Processing solutions having a pH of from about 4 to about 11 are also useful for developing imaged elements in the absence of post-rinse and gumming steps after development (so called “single bath development”). Such processing solutions contain in most cases hydrophilic polymers like gum Arabic, polyvinyl alcohol, poly(acrylic acid), or other hydrophilic polymers to protect the developed plate against fingerprints and to prevent toning of the plate when used on a printing press.

Generally, a processing solution is applied to the imaged element by rubbing or wiping the outer layer with an applicator containing the developer. Alternatively, the imaged element can be brushed with the processing solution or it may be applied by spraying the outer layer with sufficient force to remove the exposed regions. Still again, the imaged element can be immersed in the procession solution. In all instances, a developed image is produced in a lithographic printing plate having excellent resistance to press room chemicals. These development processes can be carried out in suitable developing processors or equipment using standard residence times and recirculation and replenishment rates.

Following this off-press development, the imaged element can be rinsed with water and dried in a suitable fashion. The dried element can also be treated with a conventional gumming solution (preferably gum arabic). In addition, a postbake operation can be carried out, with or without a blanket exposure to UV or visible radiation. Alternatively, a post-UV floodwise exposure (without heat) can be used to enhance the performance of the imaged element.

In alternative embodiments, with or without a post-exposure baking step after imaging and before development, the imaged elements can be developed “off-press” using a gum processing solution or single bath developer as described below. A gum solution is typically an aqueous liquid that comprises one or more surface protective compounds capable of protecting the lithographic image of the printing plate against contamination (for example, oxidation, fingerprints, dust or scratches). There are generally two types of “gum” solutions known in the art: (1) a “bake”, “baking”, or “pre-bake” gum usually contains one or more compounds that do not evaporate at the usual pre-bake temperatures used for making lithographic printing plates, typically an anionic or nonionic surfactant, and (2) a “finisher” gum that usually contains one or more hydrophilic polymers (both synthetic and naturally-occurring, such as gum Arabic cellulosic compounds, (meth)acrylic acid polymers, and polysaccharides) that are useful for providing a protective overcoat on a printing plate. The gums used in the practice of these embodiments would be generally considered “pre-bake” gums, and thus, usually lack the hydrophilic polymers.

The gum may be provided in diluted or concentrated form. The amounts of components described below refer to amount in the diluted gum that is likely its form for use in the practice of the invention. However, it is to be understood that concentrated gums can be used and the amounts of various components (such as the anionic surfactants) would be correspondingly increased.

The gum is an aqueous solution that generally has a pH greater than 3 and up to about 9 as adjusted using a suitable amount of a base. The viscosity of the gum can be adjusted to a value of from about 1.7 to about 5 cP by adding a suitable amount of a viscosity increasing compound such as a poly(vinyl alcohol) or poly(ethylene oxide).

In addition, these gums have one or more anionic surfactants as the only essential component, even though optional components (described below) can be present if desired. Useful anionic surfactants include those with carboxylic acid, sulfonic acid, or phosphonic acid groups (or salts thereof). Anionic surfactants having sulfonic acid (or salts thereof) groups are particularly useful. For example, anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypolyoxyethylenepropylsulfonates, salts of polyoxyethylene alkylsulfonophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphate alkylester, salts of alkylsulfuric esters, sulfuric esters of polyoxyethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhdyride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful as the primary or “first” anionic surfactant. Such surfactants can be obtained from various suppliers as described in McCutcheon's Emulsifiers & Detergents, 2007 Edition.

Particular examples of such surfactants include but are not limited to, sodium dodecylphenoxyoxybenzene disulfonate, the sodium salt of alkylated naphthalenesulfonate, disodium methylene-dinaphthalene disulfonate, sodium dodecylbenzenesulfonate, sulfonated alkyl-diphenyloxide, ammonium or potassium perfluoroalkylsulfonate and sodium dioctylsulfosuccinate.

The one or more anionic surfactants are generally present in an amount of at least 1 weight %, and typically from about 1 to about 45 weight %, or from about 3 to about 30 weight % (based on the weight of the gum).

Two or more anionic surfactants (“first”, “second”, etc.) can be used in combination. In such mixtures, a first anionic surfactant, such as an alkyldiphenyloxide disulfonate, can be present generally in an amount of at least 1 weight % and typically from about 3 to about 30 weight %. A second surfactant can be present (same or different from the first anionic surfactant) in a total amount of at least 0.1 weight %, and typically from about 2 to about 30 weight %. Second or additional anionic surfactants can be selected from the substituted aromatic alkali alkyl sulfonates and aliphatic alkali sulfates. One particular combination of anionic surfactants includes one or more alkyldiphenyloxide disulfonates and one or more aromatic alkali alkyl sulfonates (such as an alkali alkyl naphthalene sulfonate).

The gums may include nonionic surfactants as described in [0029] or hydrophilic polymers described in [0024] of EP 1,751,625 (noted above), incorporated herein by reference. Particularly useful nonionic surfactants include Mazol® PG031-K (a triglycerol monooleate, Tween® 80 (a sorbitan derivative), Pluronic® L62LF (a block copolymer of propylene oxide and ethylene oxide), and Zonyl® FSN (a fluorocarbon), and a nonionic surfactant for successfully coating the gum onto the printing plate surface, such as a nonionic polyglycol. These nonionic surfactants can be present in an amount of up to 10 weight %, but at usually less than 2 weight %.

Other optional components of the gum include inorganic salts (such as those described in [0032] of U.S. Patent Application 2005/0266349, noted above), wetting agents (such as a glycol), a metal chelating agents, antiseptic agents, anti-foaming agents, ink receptivity agents (such as those described in [0038] of U.S. Pat. No. '349), and viscosity increasing agents as noted above. The amounts of such components are known in the art. Calcium ion chelating agents are particularly useful, including but not limited to, polyaminopoly-carboxylic acids, aminopolycarboxylic acids, or salts thereof, [such as salts of ethylenediaminetetraacetic acid (EDTA, sodium salt)], organic phosphonic acids and salts thereof, and phosphonoalkanetricarboxylic acids and salts thereof. Organic amines may also be useful. A chelating agent may be present in the gum in an amount of from about 0.001 to about 1 weight %.

Generally, the gum is applied to the imaged element by rubbing, spraying, jetting, dipping, coating, or wiping the outer layer with the gum or a roller, impregnated pad, or applicator containing the gum. For example, the imaged element can be brushed with the gum, or the gum may be poured on or applied by spraying the outer layer with sufficient force to remove the exposed regions using a spray nozzle system as described for example in [0124] of EP 1,788,431A2 (noted above). Still again, the imaged element can be immersed in the gum and rubbed by hand or with an apparatus.

The gum can also be applied in a gumming unit (or gumming station) that has at least one roller for rubbing or brushing the printing plate while the gum is applied during development. By using such a gumming unit, the non-exposed regions of the imaged layer may be removed from the substrate more completely and quickly. The gum used in development can be collected in a tank and the gum can be used several times, and replenished if necessary from a reservoir of gum. The gum replenisher can be of the same concentration as that used in development, or be provided in concentrated form and diluted with water at an appropriate time.

Following off-press development, a postbake operation can be carried out, with or without a blanket or floodwise exposure to UV or visible radiation. The imaged and developed element can be baked in a postbake operation to increase run length of the resulting imaged element. Baking can be carried out, for example at from about 170° C. to about 240° C. for from about 7 to about 10 minutes, or at about 120° C. for 30 minutes. Alternatively, a blanket UV or visible radiation exposure can be carried out, without a postbake operation.

Thus, whatever the developing process, the method of this invention can be carried out by omitting the post-exposure baking step and removing predominantly only the non-exposed regions by development to provide a negative-working lithographic printing plate having a hydrophilic aluminum-containing substrate.

Alternatively, predominantly only the exposed regions are removed during developing to provide a positive-working lithographic printing plate having a hydrophilic aluminum-containing substrate.

As one skilled in the art would know, such development processes may remove insignificant amounts of the exposed regions (for negative-working) or non-exposed regions (for positive-working), but not enough to significantly affect the desired image.

Printing can be carried out by applying a lithographic ink and fountain solution to the printing surface of the imaged and developed element. The fountain solution is taken up by the non-imaged regions, that is, the surface of the hydrophilic substrate revealed by the imaging and development steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

### Embodiments

The present invention includes but is not limited to, the following embodiments:

Item 1:

An imageable element comprising a substrate and having thereon a radiation-sensitive imageable layer that comprises at least one pigment colorant that does not change color when heated, and at least one dye that can change color when heated, wherein the dye is soluble in the solvent or mixture of solvents used to coat the radiation-sensitive imageable layer on the substrate and the pigment colorant is not, and

wherein the pigment colorant and the dye independently have a maximum absorption of from about 480 to about 700 nm.

Item 2:

The element of item 1 wherein the pigment colorant is a phthalocyanine, perylene, or azo pigment that is present in an amount of at least 0.2 weight %.

Item 3:

The element of item 1 or 2 wherein the dye is present in an amount of at least 0.2 weight %.

Item 4:

The element of any of items 1 to 3 wherein the pigment colorant and dye are independently present at from about 0.2 to about 20 weight %.

Item 5:

The element of any of items 1 to 4 wherein imageable element is a negative-working lithographic printing plate precursor having a radiation imaging sensitivity of from about 300 to about 450 nm or from about 700 to about 1400 nm, and the radiation-sensitive imageable layer comprises a composition that provides either free radicals or acids for polymerization.

Item 6:

The element of any of items 1 to 5 wherein the imageable element is a positive-working lithographic printing plate precursor.

Item 7:

The element of any of items 1 to 6 that is a multilayer lithographic printing plate precursor comprising inner and outer layers and the pigment colorant and the dye are present in the inner layer.

Item 8:

The element of any of items 1 to 7 wherein the dye is a cyanine, triarylmethane, azo, or merocyanine dye.

Item 9:

The element of any of items 1 to 8 wherein the radiation-sensitive layer has been coated onto the substrate in one or more solvents that having hydroxyl, ester, ether, carbonyl, carboxy, amide, or nitrile groups and have a boiling point of from about 30 to about 250° C.

Item 10:

The element of any of items 1 to 9 wherein the pigment colorant and the dye independently have a maximum absorption of from about 600 to about 700 nm.

Item 11:

A method of providing a lithographic printing plate comprising:

A) imagewise exposing the imageable element of any of items 1 to 10 to provide exposed and non-exposed regions,

B) processing the imagewise exposed imageable element to provide a lithographic printing plate, and

C) baking the lithographic printing plate at a temperature of from about 150 to about 300° C.,

wherein the optical density of the lithographic printing plate, as measured using a cyan filter:

i) after steps A and B and before step C is at least 0.7,

ii) after steps A, B, and C is at least 0.5,

the difference between the optical density of the exposed regions before step A and the optical density of the exposed regions after step B but before step C, is less than 0.05, and

the difference between the optical density of the exposed regions between steps B and C, and the optical density of the exposed regions after step C, is at least 0.2.

Item 12:

The method of item 11 wherein the optical density, as measured using a cyan filter of the lithographic printing plate before step A is from about 0.9 to about 1.2.

Item 13:

The method of item 11 or 12 wherein the difference between the optical density of the exposed regions between steps B and C, and the optical density of the exposed regions after step C, is from about 0.2 to about 0.4.

Item 14:

The method of any of items 11 to 13 wherein the imagewise exposure is carried out at a wavelength of from about 300 to about 450 nm.

Item 15:

The method of any of items 11 to 14 wherein the imagewise exposure is carried out at a wavelength of from about 700 to about 1400 nm.

Item 16:

The method of any of items 11 to 15 wherein the imageable element is a negative-working lithographic printing plate precursor and the non-exposed regions are removed during the processing.

Item 17:

The method of any of items 11 to 16 wherein the pigment colorant and the dye in the imageable element independently have a maximum absorption of from about 480 to about 700 nm.

The following examples are provided to illustrate the practice of the invention but are by no means intended to limit the invention in any manner.

### EXAMPLES

The following compounds and abbreviations were used in the examples:

| | |
|---|---|
| IR Dye 1 | 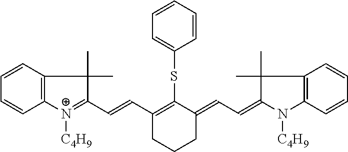 |
| | 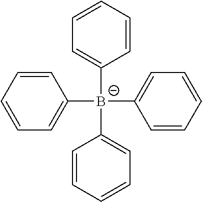 |
| IR Dye 2 | 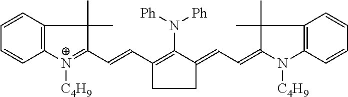 |
| | 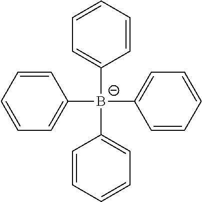 |
| Kayamer | Ester of 1 mol phosphoric acid and 1.5 mol hydroxyethyl |
| PM-2 | methacrylate, available from Nippon Kayaku/Japan |
| Monomer 1 | mixture 1 part of NK-Ester BPE-200 (ethoxylated |
| | Bisphenol A having methacrylic end groups available from |
| | Shin Nakamura/Japan) and 3 parts of a 80% solution in |
| | methyl ethyl ketone of an oligomer prepared by reacting |
| | Desmodur ® N100 (trifunctional isocyanate (biuret of |
| | hexamethylene diisocyanate), available from Bayer/ |
| | Germany) with hydroxyethyl acrylate and pentaerythritol |
| | triacrylate; amount of double bonds; 0.5 double bonds per |
| | 100 g, when all isocyanate groups have reacted |
| NK Ester | ethoxylated Bisphenol A having methacrylic end groups |
| BPE-200 | available from Shin Nakamura/Japan |
| Dye 1 | Triarylmethane dye D11 available from Eastman Kodak |
| | Company |
| Dye 2 | Basonyl Violet 610 available from BASF/Germany |
| Pigment 1 | dispersion in propylene glycol monomethyl ether |
| | containing 9 wt. % of copper phthalocyanine and 1 wt. % |
| | of a poly(vinyl acetal) binder containing 39.9 mol % vinyl |
| | alcohol, 1.2 mol % vinyl acetate, 15.4 mol % acetal groups |
| | from acetaldehyde, 36.1 mol % acetal groups from |
| | butyraldehyde and 7.4 acetal groups from 4-formylbenzoic |
| | acid |
| Pigment 2 | Cu-phthalocyanine MHI A037M available from Mikuni |
| | Color Ltd. |

### Invention Examples 1 to 4 and Comparative Examples 1 to 4

An electrochemically roughened and anodized aluminum foil with an oxide weight of 3 g/m² was subjected to a post treatment using an aqueous solution of poly(vinyl phosphoric acid). The average roughness of the surface was 0.55 μm. Coating compositions corresponding to TABLES 1 and 2 were applied to this substrate after filtering with a wire bar coater. The coatings were dried for 4 minutes at 90° C. The dry coating weights were 1.4 g/m² for the formulations sensitized for 810 to 830 nm (TABLE II).

The obtained samples were overcoated with an aqueous solution of poly(vinyl alcohol) (Celvol® 203 from Air Products, having a hydrolysis degree of 88%) with a wire bar coater to get a printing plate precursor having a dry coating weight after drying for 4 minutes at 90° C. The coating weight of the poly(vinyl alcohol) top layer was 1 g/m².

The UGRA/FOGRA Postscript Strip version 2.0 EPS (available from UGRA), which contains different elements for evaluating the quality of the copies, was used for imaging plates of Invention Example 4 and Comparative Example 4 with Trendsetter 3244 from Kodak (830 nm). Photospeed of the plates exposed at 830 nm was evaluated by exposing the plate with different energies. The minimum energy required for the proper exposure of a 1-pixel circular line was defined as the photo speed of the plate.

After washing off the water-soluble overcoat with water the imaged elements were developed using the Kodak 980 developer and baking gum 804 from Kodak was applied.

The plate baking carried out in a stationary baking oven for 4 minutes at 250° C. The optical density was measured with an X-Rite 502 using the cyan filter for the exposed and developed plates, with and without baking.

TABLE II shows that in the imageable elements of the invention, the combination of pigment colorant and dye (Invention Examples 1 to 4) allows a good differentiation of the imaged areas of the baked and unbaked printing plates without losing contrast to such an extent that video cameras in punch-bender machines can not automatically detect the register marks as in case of using only the soluble dyes (Comparative Examples 2 and 4). Comparative Examples 1 and 3 demonstrate that the use of pigments colorants as the only colorants does not allow a determination of whether the printing plate has been baked or not.

TABLE I
(dry coating weight of 1.4 g/m²)

| | | |
|---|---|---|
| 32 | ml | propylene glycol monomethyl ether |
| 8 | ml | methyl ethyl ketone |
| 0.09 | g | IR dye corresponding to TABLE II |
| 2.28 | g | copolymer of benzyl methacrylate/allyl |
| | | methacrylate/methacrylic acid molar ratio of |
| | | 20/60/20 |
| 0.15 | g | bis(4-cumyl) iodonium tetraphenyl borate |
| 4.3 | g | radical polymerizable monomer/oligomer |
| | | corresponding to TABLE II |
| 0.2 | g | Kayamer PM-2 |
| 1.8 | g | pigment dispersion corresponding to TABLE II |
| 0.09 | g | soluble dye corresponding to TABLE II |
| 0.15 | g | 1H-1,2,4-triazole-5-thiol |

TABLE II

| | | | Free | | | | | | O.D. | |
|---|---|---|---|---|---|---|---|---|---|---|
| | | | Radical | | | | | | processed | |
| | | | polymer- | Pigment | | Exposure | O.D. of | | plate minus | |
| | | Binder | izable | Colorant | | Energy | processed | O.D. of | O.D. baked | Color of the |
| | IR Dye | Polymer | Monomer | Dispersion | Soluble Dye | [mJ/cm²] | plate | baked plate | plate | baked plate |
| Invention | 1 | 1 | 1 | 1 | 1 | 90 | 1.10 | 0.78 | 0.32 | blue |
| Example 1 | | | | | | | | | | |
| Invention | 2 | 1 | 1 | 1 | 1 | 90 | 1.08 | 0.76 | 0.32 | blue |
| Example 2 | | | | | | | | | | |
| Invention | 1 | 1 | 1 | 1 | 2 | 100 | 1.19 | 0.81 | 0.38 | blue |
| Example 3 | | | | | | | | | | |
| Invention | 1 | 1 | 1 | 2 | 1 | 90 | 1.10 | 0.72 | 0.38 | blue |
| Example 4 | | | | | | | | | | |
| Comparative | 1 | 1 | 1 | 1 | — | 90 | 0.95 | 0.84 | 0.11 | blue |
| Example 1 | | | | | | | | | | |
| Comparative | 1 | 1 | 1 | — | 1 | 90 | 0.91 | 0.44 | 0.47 | brown |
| Example 2 | | | | | | | | | | |
| Comparative | 1 | 1 | 1 | 2 | — | 90 | 0.94 | 0.83 | 0.11 | blue |
| Example 3 | | | | | | | | | | |
| Comparative | 1 | 1 | 1 | — | 2 | 110 | 0.93 | 0.37 | 0.56 | brown |
| Example 4 | | | | | | | | | | |

The invention has been described in detail with particular reference to certain preferred embodiments thereof, but it will be understood that variations and modifications can be effected within the spirit and scope of the invention.

1. A method of providing a lithographic printing plate comprising:
A) imagewise exposing the imageable element comprising a substrate and comprising thereon a radiation-sensitive imageable layer to provide exposed and non-exposed regions in the radiation-sensitive imageable layer,
the radiation-sensitive imageable layer comprising at least one pigment colorant that does not change color when heated, and at least one dye that can change color when heated, wherein the dye is soluble in the solvent or mixture of solvents used to coat the radiation-sensitive imageable layer on the substrate and the pigment colorant is not, and wherein the pigment colorant and the dye independently have a maximum absorption of from about 480 to about 700 mu,
B) processing the imagewise exposed imageable element to provide a lithographic printing plate, and
C) baking the lithographic printing plate at a temperature of from about 150° C. to about 300° C.,
wherein the optical density of the lithographic printing plate, as measured using a cyan filter, of the exposed regions:
i) after steps A and B and before step C is at least 0.7,
ii) after steps A, B, and C is at least 0.5,
the difference between the optical density of the exposed regions before step A and the optical density of the exposed regions after step B but before step C, is less than 0.05, and
the difference between the optical density of the exposed regions between steps B and C, and the optical density of the exposed regions after step C, is at least 0.2.

2. The method of claim 1, wherein the optical density in exposed regions, as measured using a cyan filter of the lithographic printing plate before step A is from about 0.9 to about 1.2.

3. The method of claim 1, wherein the difference between the optical density of the exposed regions between steps B and C, and the optical density of the exposed regions after step C, as measured using a cyan filter, is from about 0.2 to about 0.4.

4. The method of claim 1, wherein the imagewise exposing is carried out at a wavelength of from about 300 nm to about 450 nm.

5. The method of claim 1, wherein the imagewise exposure is carried out at a wavelength of from about 700 nm to about 1400 nm.

6. The method of claim 1, wherein the imageable element is a negative-working lithographic printing plate precursor comprising a radiation-sensitive imageable layer comprising a free radically polymerizable monomer, oligomer, or polymer, and an initiator composition that generates free radicals upon response to the imagewise exposing, and the non-exposed regions are removed during the processing.

7. The method of claim 1, wherein the pigment colorant is a phthalocyanine, perylene, or azo pigment that is present in an amount of at least 0.2 weight %.

8. The method of claim 1, wherein the dye is present in the imageable layer in an amount of at least 0.2 weight %.

9. The method of claim 1, wherein the pigment colorant and dye are independently present in the imageable layer in an amount of from about 0.2 to about 20 weight %.

10. The method of claim 1, wherein imageable element is a negative-working lithographic printing plate precursor having a radiation imaging sensitivity of from about 300 nm to about 450 nm.

11. The method of claim 1, wherein the imageable element is a negative-working lithographic printing plate precursor having a radiation imaging sensitivity of from about 700 nm to about 1400 nm.

12. The method of claim 1, wherein the imageable element is a positive-working lithographic printing plate precursor.

13. The method of claim 1, wherein the at least one dye is a cyanine, triarylmethane, azo, or merocyanine dye.

14. The method of claim 1, wherein the pigment colorant and the at least one dye independently have a maximum absorption of from about 600 nm to about 700 nm.

15. The method of claim 1, wherein the at least one dye is capable of changing color during the baking.

16. The method of claim 1, wherein the lithographic printing plate exhibits an optical density change in exposed regions after imagewise exposure, before and after the baking, as measured using a cyan filter, of at least 0.7.

17. The method of claim 1, wherein the lithographic printing plate exhibits an optical density change in exposed regions after imagewise exposure, before and after the baking, as measured using a cyan filter, of from about 0.9 to about 1.2.
